(19) United States
(12) Patent Application Publication
(10) Pub. No.: US 2022/0353956 A1
(43) Pub. Date: Nov. 3, 2022

(54) WINDOWS FOR RAPID THERMAL PROCESSING CHAMBERS

(71) Applicant: Applied Materials, Inc., Santa Clara, CA (US)

(72) Inventors: Christopher S. OLSEN, Fremont, CA (US); Tobin KAUFMAN-OSBORN, Sunnyvale, CA (US); Samuel C. HOWELLS, Portland, OR (US)

(21) Appl. No.: 17/729,715

(22) Filed: Apr. 26, 2022

Related U.S. Application Data
(60) Provisional application No. 63/181,626, filed on Apr. 29, 2021.

(51) Int. Cl. H05B 3/02; H05B 3/00

(52) U.S. Cl. CPC H05B 3/02; H05B 3/0047; H05B 2203/008

(57) ABSTRACT

A window assembly for a thermal processing chamber applicable for thermal processing of a semiconductor substrate is provided. The window assembly includes an upper window, a lower window, and a plurality of linear reflectors disposed between the upper window and the lower window. The plurality of linear reflectors extend lengthwise parallel to each other and parallel to a plane of the window assembly. The window assembly includes a pressure control region defined between the upper window, the lower window, and side surfaces of each linear reflector.

### CROSS-REFERENCE TO RELATED APPLICATIONS

This application claims benefit of U.S. Provisional Patent Application No. 63/181,626, filed Apr. 29, 2021, which is herein incorporated by reference in its entirety.

### BACKGROUND

### Field

Embodiments disclosed herein generally relate to thermal processing of semiconductor substrates. More specifically, embodiments disclosed herein are related to windows for rapid thermal processing chambers for thermal processing of semiconductor substrates.

### Description of the Related Art

Rapid thermal processing (RTP) is one thermal processing technique that allows rapid heating and cooling of a substrate, such as a silicon wafer. RTP substrate processing applications include annealing, dopant activation, rapid thermal oxidation, and silicidation, among others. In some examples, peak processing temperatures can range from about 450° C. to about 1100° C. In one type of RTP chamber, heating is performed with numerous lamps disposed in a lamphead above or below the substrate being processed. The lamps may be arranged in a matrix, honeycomb, or linear formation in the RTP lamphead of the RTP chamber.

A body portion of the RTP chamber located between the lamps and the substrate includes a window to enable transmission of radiation therethrough. The body portion of the RTP chamber encloses a processing region in which the substrate is located during processing. A pressure in the processing region may be controlled during processing. For example, atmospheric pressure or vacuum pressure may be used in the processing region depending on the RTP substrate processing application. When the processing region is at vacuum pressure, a pressure differential exists between inside and outside the RTP chamber. In order to prevent damage to the RTP chamber caused by the pressure differential, RTP chambers which are capable of operating at vacuum pressures may include thicker windows compared to RTP chambers which are only capable of operating at atmospheric pressure. However, in order to accommodate the use of thicker windows, corresponding lamps may be spaced farther from the substrate which reduces temperature control uniformity.

Therefore, there is a need for improved RTP chambers operating at vacuum pressures.

### SUMMARY

Embodiments of the disclosure are generally related to rapid thermal processing chambers, and components thereof such as windows, for thermal processing of semiconductor substrates.

In one embodiment, a window assembly for a thermal processing chamber applicable for semiconductor manufacturing is provided, the window assembly including an upper window, a lower window, and a plurality of linear reflectors disposed between the upper window and the lower window. The plurality of linear reflectors extend lengthwise parallel to each other and parallel to a plane of the window assembly. The window assembly includes a pressure control region defined between the upper window, the lower window, and side surfaces of each linear reflector.

In another embodiment, a window assembly for a thermal processing chamber applicable for semiconductor manufacturing includes a window body and a plurality of lenses disposed on a surface of the window body. An optical axis of each lens is perpendicular to a plane of the window body.

In another embodiment, a thermal processing chamber applicable for semiconductor manufacturing includes one or more side walls surrounding a processing region, a substrate support within the processing region, the substrate support having a substrate supporting surface, and a window assembly disposed above the one or more side walls. The window assembly includes an upper window, a lower window, and a plurality of linear reflectors disposed between the upper window and the lower window. The plurality of linear reflectors extend lengthwise parallel to each other and parallel to a plane of the window assembly. The window assembly includes a pressure control region defined between the upper window, the lower window, and side surfaces of each linear reflector. The thermal processing chamber includes a lamphead disposed above the window assembly.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A is a side sectional view of a thermal processing chamber, according to one embodiment.

FIGS. 1B and 1C are schematic top views illustrating two different exemplary window assemblies which may be used in the thermal processing chamber of FIG. 1A.

FIG. 1D is an enlarged side sectional view of a portion of the thermal processing chamber of FIG. 1A illustrating an exemplary reflector in more detail.

FIG. 2A is an enlarged side sectional view illustrating another exemplary reflector which may be used in the window assembly of FIG. 1A.

FIG. 2B is an enlarged side sectional view illustrating yet another exemplary reflector which may be used in the window assembly of FIG. 1A.

FIG. 3A is a side sectional view of the thermal processing chamber of FIG. 1A illustrating a different window assembly installed therewith.

FIG. 3B is a schematic top view of the window assembly of FIG. 3A.

FIG. 3C is an enlarged side sectional view of a portion of the thermal processing chamber of FIG. 3A.

FIG. 4 is an enlarged side sectional view illustrating another exemplary window assembly which may be used in the thermal processing chamber of FIG. 3A.

To facilitate understanding, common words have been used, where possible, to designate identical elements that are common to the figures. It is contemplated that elements disclosed in one embodiment may be beneficially utilized on other embodiments without specific recitation.

### DETAILED DESCRIPTION

The present disclosure relates generally to thermal processing of semiconductor substrates. More specifically, embodiments disclosed herein are related to windows for rapid thermal processing chambers for thermal processing of semiconductor substrates.

Apparatus and/or methods disclosed herein provide improved windows for vacuum pressure RTP processes. In one example process, post-nitridation anneal of silicon oxynitride (e.g., SiON) films is performed at low Torr (e.g., 0.1-5 Torr) partial pressure of oxygen. Because ultra-high dilution would be required at atmospheric pressure to achieve low Torr partial pressures of oxygen, the post-nitridation anneal process is implemented at vacuum pressure. In another example, vacuum pressure RTP is used for radical oxidation processes which use atomic oxygen radicals produced by hydrogen-oxygen combustion because the combustion only occurs at pressures of about 10 Torr or less. In yet another example, vacuum pressure RTP is used with atomic oxygen radicals produced in a remote plasma source because the atomic radicals are unstable at pressures greater than about 3 Torr. Each of the aforementioned processes, among others, benefit from the apparatus and/or methods of the present disclosure.

Embodiments disclosed herein provide a window assembly comprising a plurality of linear reflectors which reflect and provide directionality to radiation emitted by one or more linear lamps of a thermal processing chamber. The linear reflectors reduce or prevent zonal overlap of the radiation within a processing region or on a substrate surface with consequent improvement of temperature control uniformity compared to conventional reflectors.

Embodiments disclosed herein provide linear reflectors having side surfaces which are shaped and/or angled to provide improved directional control of radiation incident on the side surfaces with consequent improvement of temperature control uniformity compared to conventional reflectors.

Embodiments disclosed herein provide linear lamps and linear reflectors which are sized to generally conform to a shape of a substrate support and/or a substrate disposed thereon so that lamp power is not wasted on heating areas outside the area of the substrate.

Embodiments disclosed herein provide a window assembly comprising a plurality of lenses which improve directionality and/or focusing of radiation emitted by one or more lamps of a thermal processing chamber back towards a direction perpendicular to a plane of the window assembly with consequent improvement of zonal radiation control and temperature control uniformity compared to conventional windows.

Embodiments disclosed herein provide a window assembly comprising a plurality of linear lenses which improve directionality and/or focusing of radiation emitted by one or more linear lamps of a thermal processing chamber for improved zonal radiation control and temperature control uniformity compared to conventional windows.

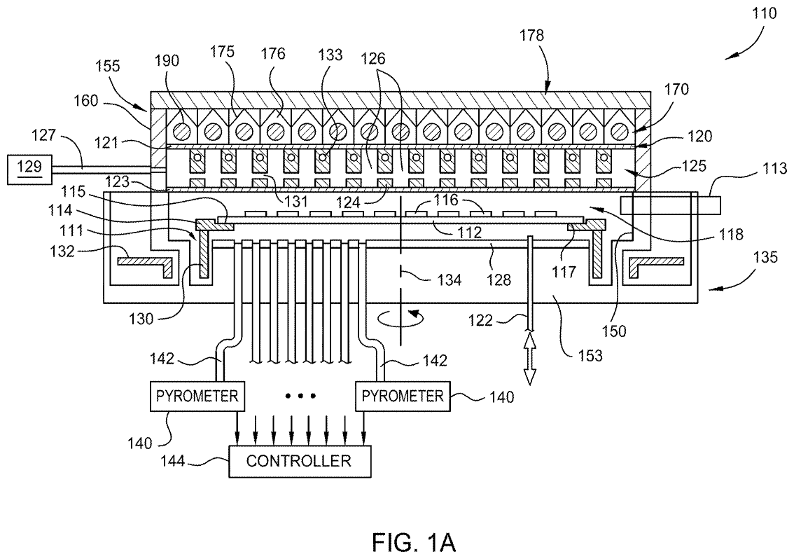

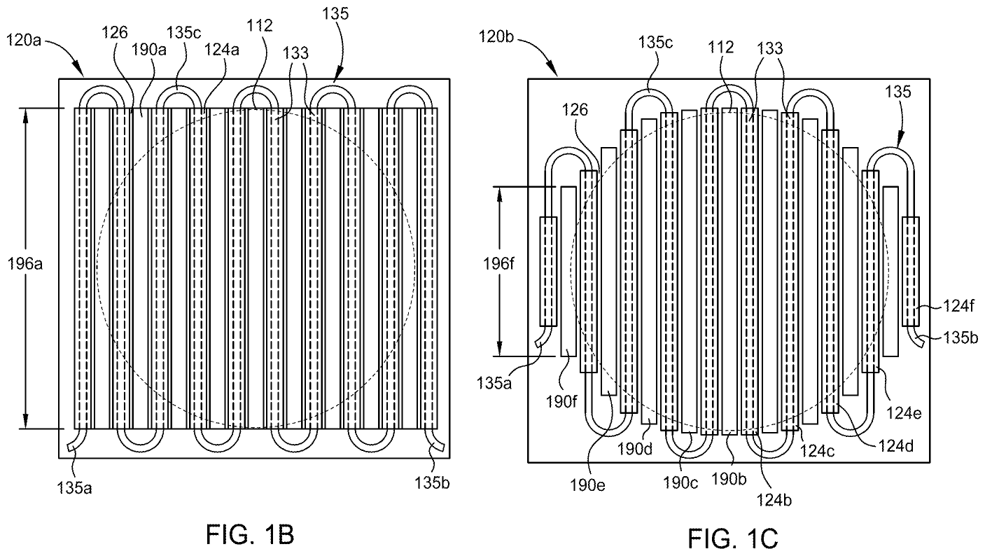

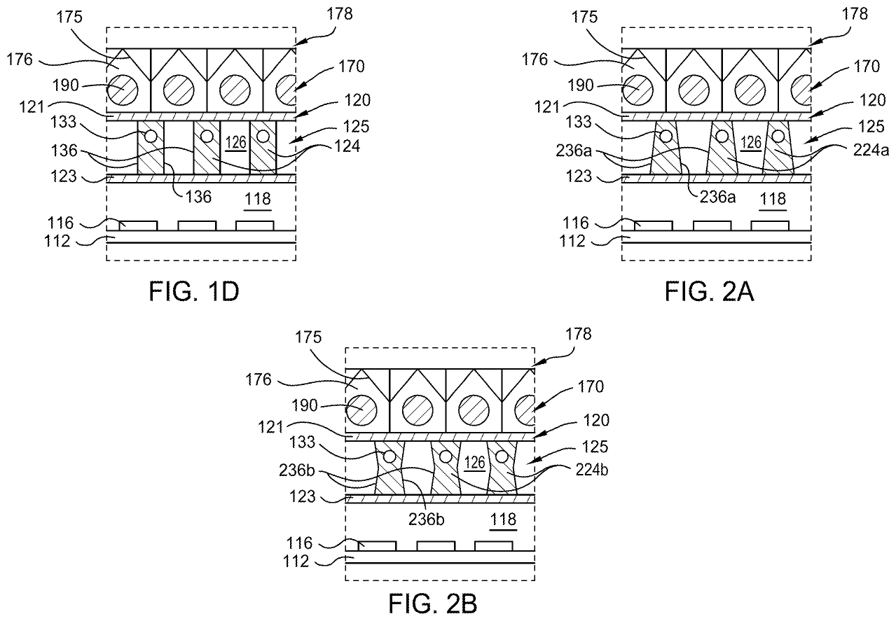

FIG. 1A is a side sectional view of a thermal processing chamber 110. The thermal processing chamber 110 can be used for rapid thermal processing (RTP) of substrates. As used herein, rapid thermal processing or RTP refers to an apparatus, chamber, or process capable of uniformly heating a substrate at rates of about 50° C./second and higher, for example, at rates of about 75° C./second to about 100° C./second or about 150° C./second to about 220° C./second. In some examples, ramp-down (cooling) rates in RTP chambers may be within a range of about 30° C./second to about 90° C./second.

The thermal processing chamber 110 includes one or more side walls 150 surrounding and/or enclosing a processing region 118 for thermally treating a substrate 112, such as a silicon substrate. The thermal processing chamber 110 includes a base 153 supporting the one or more side walls 150. The thermal processing chamber 110 includes a window assembly 120 disposed above the one or more side walls 150, a lamphead 155 disposed above the window assembly 120, and a reflector assembly 178 disposed above the lamphead 155. The window assembly 120 is transparent to enable transmission of radiation therethrough. “Radiation”, as used herein, refers to any type of electromagnetic radiation (e.g., thermal radiation which includes ultraviolet (UV) light, visible light, and infrared (IR) light). “Transparent”, as used herein, means most radiation of a given wavelength is transmitted. Thus, a “transparent” object, as used herein, is an object that transmits most incident radiation of a given wavelength of interest. As used herein, if an object is “transparent” to visible light, that object transmits most incident light of a visible wavelength. Likewise, if an object is “transparent” to infrared light, that object transmits most incident light of an infrared wavelength. Likewise, if an object is “transparent” to ultraviolet light, that object transmits most incident light of an ultraviolet wavelength.

A substrate support 111 is located within the processing region 118. The substrate support 111 is rotatable. The substrate support 111 includes an annular support ring 114 and a rotatable support cylinder 130. A rotatable flange 132 is positioned outside the processing region 118 and magnetically coupled to the support cylinder 130. An actuator (not shown) may be used to rotate the flange 132 about a centerline 134 of the thermal processing chamber 110. In one example, a bottom of the support cylinder 130 may be magnetically levitated and rotated by a rotating magnetic field produced in coils surrounding the support cylinder 130.

The substrate 112 is supported on its periphery by the annular support ring 114 of the substrate support 111. An edge lip 115 of the annular support ring 114 extends inward and contacts a portion of a backside of the substrate 112 on a substrate supporting surface 117 of the edge lip 115. The substrate 112 is oriented such that features 116 already formed on a front surface of the substrate 112 face towards the lamphead 155.

A port 113 to the processing region 118 of the thermal processing chamber 110 is used to transfer substrates to and from the thermal processing chamber 110. A plurality of lift pins 122, such as three lift pins, are extended and retracted to support the back side of the substrate 112 when the substrate 112 is disposed in, or removed from, the thermal processing chamber 110. Alternately, the plurality of lift pins 122 may remain stationary while the substrate support 111 is moved to effect extension and retraction of the lift pins 122 relative to the substrate support 111.

The processing region 118 is defined on an upper side thereof by the window assembly 120. The window assembly 120 separates the lamphead 155 from the processing region 118. The window assembly 120 is described in more detail below.

The lamphead 155 is used to heat the substrate 112 during thermal processing. The lamphead 155 includes a housing 160 and an arrangement of lamps 170 disposed within the housing 160. The housing may be formed from metal, such as stainless steel, or other suitable materials. The arrangement of lamps 170 includes a plurality of lamps 190. Examples of suitable lamps to be used as the lamps 190 can include tungsten-halogen lamps, mercury vapor lamps, infrared lamps, and ultraviolet lamps. The lamps 190 provide heat to the processing region 118 to raise the temperature of the substrate 112. As shown in FIG. 1A, the lamps 190 are linear lamps which are arranged side-to-side and extend lengthwise parallel to each other and parallel to a plane of the window assembly 120. The plane of the window assembly refers to a plane which passes lengthwise through the window assembly (i.e. aligned with a long axis thereof) and/or a plane which is parallel to an upper or lower surface of window assembly. “Linear lamp”, as used herein, refers to a lamp having a radiation source (e.g., a source of UV, IR, or visible light) which extends lengthwise in a first direction by a distance greater than a width of the radiation source measured in a second direction perpendicular to the first direction. In one example, the linear lamp includes an elongated bulb which surrounds one or more radiation emitting wires or filaments. In some other examples, the lamps 190 may be round or single-source lamps having a radiation source with about equal dimensions in the first and second directions. In such examples, the lamps 190 may be arranged in a matrix or honeycomb formation.

In one example, one or more of the lamps 190 may be segmented lamps which are configured to direct heat to control the temperature of a particular zone on the substrate 112, such as to a ring-shaped zone on the substrate 112 as the substrate 112 is rotated by the rotatable substrate support 111. Radiation emitting elements, for example filaments, of the segmented lamps may be arranged into zones, for example radial zones, corresponding to areas of a substrate 112 on the substrate support 111 to be heated. One or more sensors, such as pyrometers, may be used to monitor the different zones allowing separate temperature control of different regions of the substrate 112. For example, more heat may be provided to an outer edge of the substrate 112 to account for the increased surface area around the outer edge. The segmented lamps and/or the emitters of the segmented lamps, may be arranged to provide any desired shape or profile of zones, for example linear zones, across the arrangement 170 from one edge to the other edge of the arrangement 170, or square or rectangular zones, which may be concentric or acentric. The lamps 190 are described in more detail below.

A reflector assembly 178 is disposed above the housing 160 of the lamphead 155 to reflect radiation back towards the substrate 112. A surface of the reflector assembly 178 may be plated with a reflective material, such as gold, aluminum, or stainless steel, such as polished stainless steel. Each lamp 190 is disposed in a reflective cavity 176. Each reflective cavity 176 is defined on top by a reflector 175. In one example, the reflector 175 may extend on either side of the corresponding lamp 190. The reflectors 175 may direct, focus, and/or shape the radiation from the lamps 190.

In some examples, the reflector assembly 178 may include cooling channels to help remove excess heat from the lamphead 155 and to assist in cooling the substrate 112 during ramp-down through the use of a coolant, such as water. Although the reflector assembly 178 is shown having a substantially flat shape, in some other examples the reflector assembly 178 may have a concave shape.

The window assembly 120 includes an upper window 121, a lower window 123, a plurality of reflectors 124 disposed between and supporting the upper window 121 and lower window 123, and a pressure control region 125 defined between the upper window 121, the lower window 123, and side surfaces of each reflector 124. Each window may be formed from a transparent material, such as quartz or fused silica (amorphous quartz). Each reflector may be formed from or plated with a reflective material, such as gold, aluminum, or stainless steel, such as polished stainless steel. In general, the reflectors 124 reflect and provide directionality to the radiation emitted by the lamps 190 to reduce or prevent zonal overlap of the radiation within the processing region 118 and/or on the substrate surface. A pressure control line 127 is in fluid communication between the pressure control region 125 and a pressure control assembly 129. The pressure control assembly 129 may include a vacuum pump, a source of purge gas (e.g., helium or another inert gas), and a throttle valve for regulating pressure within the pressure control region 125. In one example, the pressure control region 125 may be operated at a vacuum pressure within a range of about 5 Torr to about 20 Torr.

The pressure control region 125 is formed of a plurality of interconnected (e.g., fluidly connected) sub-regions 126 which are spaced laterally from each other in a direction parallel to a plane of the window assembly 120 and in alignment with each of the corresponding lamps 190 in a direction perpendicular to the plane of the window assembly 120. As shown, the sub-regions 126 are coupled together by corresponding flow passages 131 disposed in a body of each reflector 124. The flow passages 131 shown are parallel to the plane of the window assembly 120. However, in some other examples the flow passages 131 may extend at an obtuse or acute angle relative to the plane of the window assembly 120. In some other examples, the sub-regions 126 may be coupled together by corresponding flow passages that are routed around each reflector 124 (e.g., above each reflector 124 and below the upper window 121 or below each reflector 124 and above the lower window 123).

As shown, a cooling channel 133 is formed in the body of each reflector 124 to help remove excess heat from the window assembly 120. The cooling channels 133 extend lengthwise through each reflector 124 perpendicular to the direction of the flow passages 131 and parallel to the plane of the window assembly 120. The cooling channels 133 form a continuous cooling path 135 which extends through each reflector 124 (shown in FIGS. 1B and 1C). The window assembly 120 is described in more detail below.

The processing region 118 is defined on a lower side thereof by the base 135 of the thermal processing chamber 110. The base 135 includes a reflector plate 128 disposed beneath the edge lip 115 of the annular support ring 114. The reflector plate 128 extends parallel to and over an area greater than a backside surface of the substrate 112 facing the reflector plate 128. The reflector plate 128 reflects radiation emitted from the substrate 112 back towards the substrate 112 to enhance an apparent emissivity of the substrate 112. A top surface of the reflector plate 128 and the backside surface of the substrate 112 form a reflective cavity for enhancing an effective emissivity of the substrate 112 to improve the accuracy of temperature measurements. A spacing between the substrate 112 and the reflector plate 128 may be about 3 mm to about 9 mm, and an aspect ratio of a width to a thickness of the reflective cavity may be greater than about 20. The top surface of the reflector plate 128 may be formed from aluminum, and may have a surface coating formed from a different material, for example a highly reflective material such as silver or gold, or a multi-layer dielectric mirror. In some examples, the reflector plate 128 may have an irregular or textured top surface, or may have a black or other colored top surface to more closely resemble a black-body wall. The reflector plate 128 is disposed on the base 135. The base 135 may include cooling channels (not shown) to help remove excess heat from the substrate 112. The cooling channels may be used especially during ramp-down through the use of a coolant, such as water.

The base 135 includes a plurality of temperature sensors 140, shown as pyrometers, to measure the temperature across a radius of the rotating substrate 112. Each sensor 140 is coupled through an optical light pipe 142 and an aperture in the reflector plate 128 to face the backside of the substrate 112. The light pipes 142 may be formed from sapphire, metal, or silica fibers, among other materials.

A controller 144 may be used to control the temperature of the substrate 112 during processing. For example, the controller 144 may be used to supply a relatively constant amount of power to the lamps 190 during a particular step of a thermal process. The controller 144 may change the amount of power supplied to the lamps 190 for different substrates or different thermal processing steps performed on a same substrate. The controller 144 may use signals from the sensors 140 as inputs to control the temperature of different radial zones on the substrate 112. The controller 144 may adjust voltages supplied to different lamps 190 to dynamically control a radiant heating intensity and pattern during the processing. In one example, the lamps 190 may be powered with a DC power supply. In another example, the lamps 190 may be powered with an AC power supply and a rectifier, such as a silicon-controlled rectifier.

Pyrometers generally measure light intensity in a narrow wavelength bandwidth of, for example, about 40 nm within a range of about 700 nm and about 1000 nm. The controller 144, or other instrumentation, may convert the measured light intensity to a temperature reading using any suitable methods.

While the thermal processing chamber 110 shown has a top heating configuration in which the lamps 190 are disposed above the substrate 112, it is contemplated that a bottom heating configuration in which the lamps 190 are disposed below the substrate 112 may benefit from the present disclosure and may be used in addition to or in place of the illustrated top heating configuration. In some examples, the front surface of the substrate 112 with the features 116 formed thereon may face away from the lamphead 155 (i.e., facing towards the sensors 140) during processing.

FIGS. 1B and 1C are schematic top views illustrating two different exemplary window assemblies which may be used in the thermal processing chamber 110 of FIG. 1A. While the lamps 190 are depicted in FIGS. 1B and 1C, the reflector assembly 178 is omitted from the figures for clarity. Referring collectively to FIGS. 1B and 1C, the cooling path 135 has an inlet 135a, an outlet 135b, and connectors 135c coupled in series between each cooling channel 133 (shown in phantom). The connectors 135c may be routed inside or outside the window assembly 120 as desired.

As described above, the lamps 190 are linear lamps which are arranged side-to-side and extend lengthwise parallel to each other and parallel to the plane of the window assembly 120. In FIG. 1B, each lamp 190a extends across approximately an entire length of the window assembly 120a, whereas in FIG. 1C, at least one of the lamps 190b-190f extends across only a portion (e.g., less than an entirety) of the length of the window assembly 120b. The reflectors 124 are linear reflectors which are arranged side-to-side and extend lengthwise parallel to each other and parallel to the plane of the window assembly 120. “Linear reflector”, as used herein, refers to a reflector which extends lengthwise in a first direction by a distance greater than a width of the reflector measured in a second direction perpendicular to the first direction. In some other examples, the reflectors may be round with about equal dimensions in the first and second directions. In such examples, the reflectors may be arranged in a matrix or honeycomb formation which matches a formation of the lamps.

As shown in the top view, the reflectors 124 and lamps 190 alternate with each other in a direction perpendicular to the lengthwise direction of the reflectors 124 and parallel to the plane of the window assembly 120. In FIG. 1B, each reflector 124a extends across approximately the entire length of the window assembly 120a, whereas in FIG. 1C, at least one of the reflectors 124b-124f extends across only a portion of the length of the window assembly 120b. In some examples, the window assembly 120 is sized to fit within the housing 160 of the thermal processing chamber 110 such that the length of the window assembly 120 corresponds to a length of the processing region 118. In such examples, each reflector 124a shown in FIG. 1B may extend across approximately the entire length of the processing region 118, whereas at least one of the reflectors 124b-124f shown in FIG. 1C extends across only a portion of the length of the processing region 118.

Referring to the window assembly 120a shown in FIG. 1B, each lamp 190a has an equal length 196a which is greater than a diameter of the substrate 112 (shown in phantom). As shown, a length of each reflector 124a is about equal to the length 196a of each lamp 190a. One advantage of the window assembly 120a is that such an arrangement 170a having equal length lamps 190a and equal length reflectors 124a is relatively simple and inexpensive to manufacture compared to more complex designs (e.g., designs having components of differing lengths such as that shown in FIG. 1C).

Referring to the window assembly 120b shown in FIG. 1C, the lamps 190b-190f have different lengths. A length of the longest lamp 190b, which may be aligned with a radial center of the processing region 118 and/or the substrate 112, may be about the same as the length 196a of each lamp 190a in FIG. 1B. The arrangement of lamps 170b shown in FIG. 1C is symmetrical about the center lamp 190b. Therefore, only the lamps 190b-190f on one side of the arrangement 170b are labeled. In some other examples, the arrangement of lamps may be non-symmetrical. Although only a length 196f of the shortest lamp 190f is shown, a length of each of the lamps 190c, 190d, 190e, and 190f decreases in order from the radial center to the outer edge of the processing region 118 and/or the substrate 112. Each of the lamps 190b-190f extends beyond the outer edge of the substrate support 111 and/or the substrate 112 so that the entire area of the substrate 112 is subjected to radiation emitted from at least one of the lamps 190b-190f.

As shown, the reflectors 124b-124f are sized according to the lengths of adjacent ones of the lamps 190b-190f. The reflectors 124b-124f shown in FIG. 1C are symmetrical with respect to the center lamp 190b. Therefore, only the reflectors 124b-124f on one side of the center lamp 190b are labeled. In some other examples, the arrangement of reflectors may be non-symmetrical. Similar to the lamps, a length of each of the reflectors 124b, 124c, 124d, 124e, and 124f decreases in order from the radial center to the outer edge of the processing region 118 and/or the substrate 112. Each of the reflectors 124b-124f extends beyond the outer edge of the substrate 112. Compared to FIG. 1B, the lamps 190b-190f and reflectors 124b-124f in FIG. 1C are sized to generally conform to the shape of the substrate support 111 and/or the substrate 112 so that lamp power is not wasted on heating areas outside the area of the substrate 112.

FIG. 1D is an enlarged side sectional view of a portion of the thermal processing chamber 110 of FIG. 1A illustrating the reflectors 124 in more detail. The reflectors 124 support the upper window 121 from underneath and provide separation between the upper window 121 and lower window 123 to define the pressure control region 125 therebetween. The reflectors 124 have reflective side surfaces 136 to reduce or prevent zonal overlap of the radiation emitted by the lamps 190 by reflecting wide angle radiation incident on the side surfaces 136 back towards a region of the substrate 112 in alignment with each of the corresponding lamps 190 in a direction perpendicular to the plane of the window assembly 120. The reflectors 124 may be formed relatively thin from about 1 cm to about 3 cm in a direction perpendicular to the plane of the window assembly 120 to limit energy absorption or other energy losses from radiation incident on the side surfaces 136. Therefore, although the reflectors 124 are shown as having a height in a direction perpendicular to the plane of the window assembly 120 greater than a width in a direction parallel to the plane of the window assembly 120, in some other examples the width may be greater than or equal to the height.

Reflection of radiation incident on the side surfaces 136 of the reflectors 124 may be directionally controlled based on a shape and/or angle of each side surface 136. As shown in FIG. 1D, the reflectors 124 are rectangular in cross-section with flat side surfaces 136 which are parallel to each other and perpendicular to the plane of the window assembly 120.

FIGS. 2A-2B are enlarged side sectional views illustrating two other exemplary reflectors 224a and 224b which may be used in the window assembly 120 of FIG. 1A. In some examples, a cross-sectional shape of each reflector may be trapezoidal (tapered) (FIG. 2A), hourglass-shaped (FIG. 2B), square, triangular, oval, diamond, any other suitable two-dimensional geometric shape or polygonal shape, or combinations thereof. In some examples, corresponding side surfaces 236a and 236b of reflectors 224a, 224b may be tapered, for example with a single angle (FIG. 2A) or two different angles (double-tapered) (FIG. 2B), curved, concave, convex, or have any other suitable cross-sectional profile. In some examples, corresponding side surfaces 236a, 236b of the same reflector 224a, 224b may diverge outwardly from each other in a downward direction (i.e., towards the lower window 123) (FIG. 2A), converge inwardly towards each other in the downward direction, or partially converge and partially diverge in the downward direction (FIG. 2B). In some implementations, use of reflectors having non-parallel side surfaces may improve the overall efficiency of the window assembly by further reducing zonal overlap and/or improving directional control of the radiation emitted by the lamps 190 compared to reflectors having parallel side surfaces.

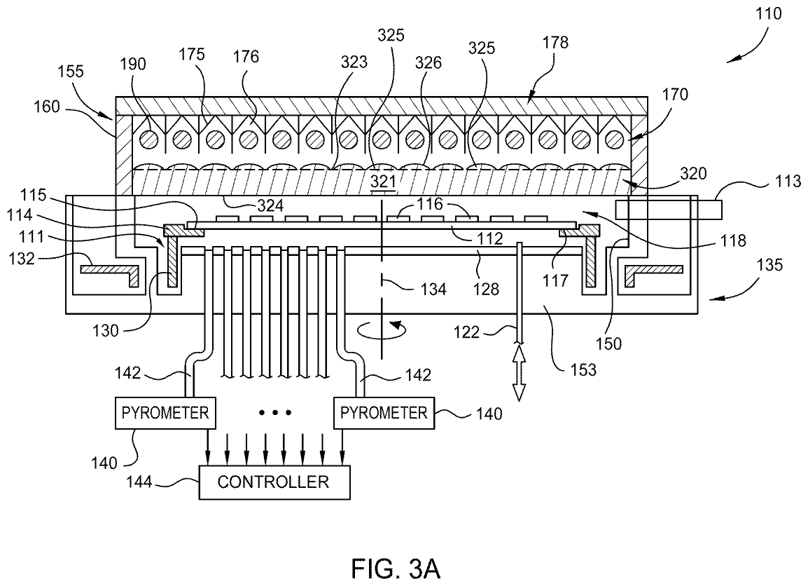

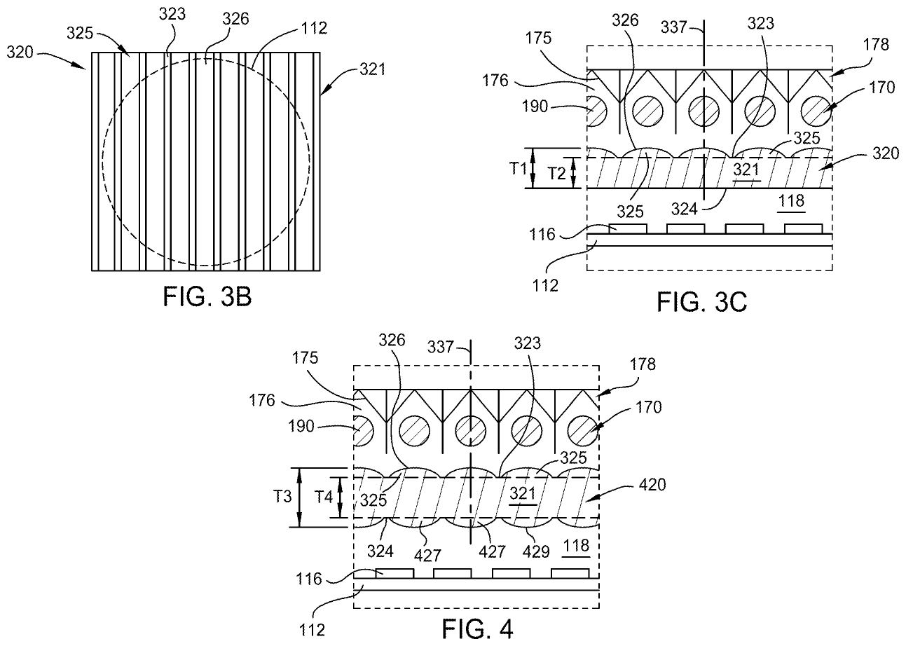

FIG. 3A is a side sectional view of the thermal processing chamber 110 of FIG. 1A illustrating a different window assembly 320 installed therewith. FIG. 3B is a schematic top view of the window assembly 320 of FIG. 3A. FIG. 3C is an enlarged side sectional view of a portion of the thermal processing chamber 110 of FIG. 3A illustrating the window assembly 320 in more detail. FIGS. 3A-3C are described together herein for clarity. The window assembly 320 includes a window body 321 having an upper surface 323 and a lower surface 324. The upper surface 323 refers to the surface indicated at least in part with a dashed line in FIGS. 3A-3B which is facing towards the lamps 190. The lower surface 324 refers to the surface opposite the upper surface 323 which is facing the processing chamber 118. As shown, the lower surface 324 is substantially flat.

The window body 321 has a plurality of lenses 325 extending upward from the upper surface 323. An optical axis 337 (shown in FIG. 3C) of each lens 325 is perpendicular to a plane of the window body 321. The lenses 325 are spaced laterally from each other in a direction parallel to the plane of the window body 321. Each lens 325 is aligned with a corresponding lamp 190 along the axis 337. In some examples, when measured parallel to the plane of the window body 321, each lens 325 and corresponding lamp 190 may be about the same width. In one example, a width of the lens 325 and corresponding lamp 190 may be about 1 cm. As shown, each lens 325 has a convex shape, which is thicker in the center than at the edge, in order to redirect wide angle radiation back towards the axis 337, which may be a vertical axis. For example, a thickness T1 measured between an outer surface 326 of each lens 325 and the lower surface 324 is greater than a thickness T2 measured between the upper surface 323 and the lower surface 324. As a result, the outer surface 326 of each lens 325 is closer to the corresponding lamp 190 than the upper surface 323 of the window body 321.

As shown in FIG. 3B, the lenses 325 are linear lenses which are arranged side-to-side and extend lengthwise parallel to each other and parallel to a plane of the window assembly 320. “Linear lens”, as used herein, refers to a lens having a linear shape which extends lengthwise in a first direction by a distance greater than a width of the lens measured in a second direction perpendicular to the first direction. In some other examples, the lenses may be round with about equal dimensions in the first and second directions. In such examples, the lenses may be arranged in a matrix or honeycomb formation which matches a formation of the lamps.

In one example, each lens 325 may be a Fresnel lens which has a succession of concentric annular rings assembled on a flat surface. Fresnel lenses may capture a greater portion of wide angle light compared to conventional lenses. Fresnel lenses may be fabricated to be much thinner than a comparable conventional lens. Therefore, one advantage of using Fresnel lenses in the window assembly 320 is that the lamps 190 can be positioned closer to the substrate 112 compared to conventional lenses which improves temperature control uniformity.

A focal length of each lens 325 may be about 5 mm to about 20 mm, such as about 5 mm to about 10 mm, such as about 5 mm, such as about 10 mm. In some examples, the window body 321 and the lenses 325 may be manufactured separately and bonded together. For example, a flat side of each lens 325 may be bonded to the flat upper surface 323. In such examples, the lenses 325 may be the same or a different material than that of the window body 321. In one example, the lenses 325 may be formed from quartz or fused silica (amorphous quartz). In some other examples, the lenses 325 may be machined into the surface of the window body 321.

In operation, the window assembly 320 is cooled by convection using a flow of forced air directed generally parallel to the plane of the window assembly 320 over the upper surface 323 of the window body 321 and over the outer surface 326 of each lens 325. The air flow may be directed between the lamps 190 and the window assembly 320.

When the window assembly 320 is configured to be used with vacuum pressure RTP, the thickness T2 measured between the upper surface 323 and the lower surface 324 may be about 20 mm to about 25 mm. In one example, a distance between the substrate 112 and the lamps 190 may be about 40 mm to about 45 mm which may be greater than a corresponding distance for atmospheric pressure RTP in which a thinner window can be used. Therefore, when a flat window is used in vacuum pressure RTP, loss of zonal radiation control may result from spreading of light rays which is more pronounced over the greater distance associated with vacuum pressure RTP. Advantageously, compared to the flat window, the window assembly 320 provides increased directionality and/or focusing of radiation (e.g., light rays) back towards the axis 337 which is perpendicular to the plane of the window assembly 320 and, consequently, improved zonal radiation control and temperature control uniformity.

FIG. 4 is an enlarged side sectional view illustrating another exemplary window assembly 420 which may be used in the thermal processing chamber 110 of FIG. 3A. The window assembly 420 is similar to the window assembly 320 of FIGS. 3A-3B except having lenses on both upper and lower surfaces of the window body 321. In addition to the upward-facing lenses 325, the window body 321 in FIG. 4 further includes a plurality of lenses 427 extending downward from the lower surface 324. In FIG. 4, the lower surface 324 is indicated at least in part with a dashed line. The lenses 427 may be constructed and arranged similar to the lenses 325. The lenses 427 are spaced laterally from each other in a direction parallel to the plane of the window assembly 420. Each lens 427 is also aligned with a corresponding lamp 190 and a corresponding lens 325 along the axis 337 which is perpendicular to the plane of the window assembly 420.

As shown, each lens 427 has a convex shape, which is thicker in the center than at the edge, in order to redirect wide angle radiation back towards the axis 337. For example, a thickness T3 measured between the outer surface 326 of each lens 325 and an outer surface 429 of each lens 427 is greater than a thickness T4 measured between the upper surface 323 and the lower surface 324. As a result, the outer surface 429 of each lens 427 is closer to the substrate 112 than the lower surface 324. During processing using window assembly 420 having lenses disposed on both the upper surface 323 and lower surface 324, a greater portion of radiation from the lamps 190 may be aligned parallel to the axis 337 compared to processing using the window assembly 320 having lenses disposed on only one surface of the window body 321. For example, each set of lenses may partially redirect radiation back towards the axis 337 so that the additive effect of the upper and lower lenses is greater than the effect of either of the upper or lower lenses alone. In some other examples, the window assembly may have lenses only on the lower surface and not the upper surface.

While the foregoing is directed to embodiments of the present disclosure, other and further embodiments of the disclosure may be devised without departing from the basic scope thereof, and the scope thereof is determined by the claims that follow.

1. A window assembly for a thermal processing chamber applicable for semiconductor processing, the window assembly comprising:
an upper window;
a lower window;
a plurality of linear reflectors disposed between the upper window and the lower window, wherein the plurality of linear reflectors extend lengthwise parallel to each other and parallel to a plane of the window assembly; and
a pressure control region defined between the upper window, the lower window, and side surfaces of each linear reflector.

2. The window assembly of claim 1, wherein the pressure control region comprises a plurality of interconnected sub-regions, wherein the plurality of sub-regions are spaced laterally from each other in a direction parallel to the plane of the window assembly and are coupled together by corresponding flow passages disposed in a body of each linear reflector.

3. The window assembly of claim 1, wherein a cooling channel is formed in a body of each linear reflector.

4. The window assembly of claim 3, wherein the cooling channels form a continuous cooling path extending through the plurality of linear reflectors.

5. The window assembly of claim 1, wherein each linear reflector extends across approximately an entire length of the window assembly.

6. The window assembly of claim 1, wherein at least one of the plurality of linear reflectors extends across only a portion of a length of the window assembly.

7. The window assembly of claim 1, wherein the side surfaces of each linear reflector are parallel to each other and perpendicular to the plane of the window assembly.

8. The window assembly of claim 1, wherein the side surfaces of each linear reflector are tapered.

9. The window assembly of claim 1, wherein the side surfaces of each linear reflector are double-tapered.

10. A window assembly for a thermal processing chamber applicable for semiconductor processing, comprising:
a window body; and
a plurality of lenses disposed on a surface of the window body, wherein an optical axis of each lens is perpendicular to a plane of the window body.

11. The window assembly of claim 11, wherein each lens comprises a convex shape.

12. The window assembly of claim 11, wherein each lens comprises a linear shape, and wherein the plurality of lenses extend lengthwise parallel to each other and parallel to the plane of the window assembly.

13. The window assembly of claim 11, wherein each lens comprises a Fresnel lens.

14. The window assembly of claim 11, wherein the plurality of lenses are disposed on only one surface of the window body.

15. The window assembly of claim 11, wherein the plurality of lenses are disposed on two opposite surfaces of the window body.

16. The window assembly of claim 11, wherein the plurality of lenses are machined into the surface of the window body.

17. The window assembly of claim 11, wherein the window body and the plurality of lenses are manufactured separately and bonded together.

18. A thermal processing chamber applicable for semiconductor processing, comprising:
one or more side walls surrounding a processing region;
a substrate support within the processing region, the substrate support having a substrate supporting surface;
a window assembly disposed above the one or more side walls, the window assembly comprising:
an upper window;
a lower window;
a plurality of linear reflectors disposed between the upper window and the lower window, wherein the plurality of linear reflectors extend lengthwise parallel to each other and parallel to a plane of the window assembly; and
a pressure control region defined between the upper window, the lower window, and side surfaces of each linear reflector; and
a lamphead disposed above the window assembly.

19. The thermal processing chamber of claim 18, wherein the lamphead comprises a plurality of linear lamps, and wherein the plurality of linear reflectors and plurality of linear lamps have an alternating arrangement in a direction parallel to the plane of the window assembly.

20. The thermal processing chamber of claim 18, wherein the plurality of linear reflectors are sized to generally conform to the shape of the substrate support.
